(19) United States
(12) Patent Application Publication
(10) Pub. No.: US 2013/0146332 A1
(43) Pub. Date: Jun. 13, 2013

(54) FORMATION OF ELECTRICALLY CONDUCTIVE PATTERN BY SURFACE ENERGY MODIFICATION

(71) Applicants: Ed S. Ramakrishnan, The Woodlands, TX (US); Robert J. Petcavich, The Woodlands, TX (US)

(72) Inventors: Ed S. Ramakrishnan, The Woodlands, TX (US); Robert J. Petcavich, The Woodlands, TX (US)

(73) Assignee: UNIPIXEL DISPLAYS ,INC., The Woodlands, TX (US)

(21) Appl. No.: 13/511,415

(22) PCT Filed: Oct. 29, 2010
(86) PCT No.: PCT/US2010/054641

§ 371 Date: Oct. 8, 2012

Related U.S. Application Data
(60) Provisional application No. 61/264,234, filed on Nov. 24, 2009.

(51) Int. Cl. H05K 3/18

(52) U.S. Cl. CPC H05K 3/182
USPC 174/250; 427/98.5; 427/96.8

(57) ABSTRACT

A method for forming a conductive pattern on a substrate surface comprises altering the surface energy of the substrate surface, depositing a catalyst-doped liquid on to said substrate surface; forming a seed layer from said deposited catalyst-doped liquid, and plating the seed layer thereby forming the conductive pattern. In some embodiments, 3-D structures are placed on the substrate to delimit the size and shape of the conductive pattern. In other embodiments, the surface energy of the areas of the substrate in which conductive material is not desired (i.e., inverse pattern) is altered (e.g., lowered) to avoid having conductive liquid adhere thereto.

### STATEMENT REGARDING FEDERALLY SPONSORED RESEARCH OR DEVELOPMENT

Not applicable.

### BACKGROUND

Circuits include one or more active and/or passive electrical components connected together by way of electrical conductors. On circuit boards, such conductors may include traces fabricated as part of the circuit board itself, wires, or deposited conductive material. Miniaturization necessitates smaller components that are in close proximity to each other.

In the evolution of electronic device manufacturing, the fabrication techniques used to print or otherwise deposit electronic wiring has ongoing challenges in advancing towards higher density electrically conductive lines and patterns. Methods to produce narrower conductive line widths and conductive patterns are of particular importance in the fabrication of, for example, semiconductor devices, electronic panels to drive optical displays (e.g., liquid crystal displays (LCDs)), and solar cell panels.

Conductive material may be deposited to form an electrically conductive line or an electrically conductive pattern. For example, a conductive line may be an electrical trace that extends between two electronic devices. A conductive pattern comprises conductive material deposited in or around a three dimensional structure, for example, conductive material in a three dimensional (3D) trench or around a 3D protrusion.

For sub-micron scale electrical conductive wiring deposition, conductive material is typically deposited onto substrates by conventional semiconductor processing techniques that include metal deposition, photolithography, and etching processes. Although effective for fabricating sub-micron electronic conductive lines, these techniques are expensive and limited to the processing of substrate sizes less than about 300 mm. In other words, semiconductor processing techniques cannot be scaled up for large area devices (>300 mm) such as LCD panels and solar panels having size dimensions that frequently exceed 1 meter. Another drawback conductive line deposition by semiconductor processing techniques is that such techniques require exposing the substrate to high processing temperatures typically in a range of about 100° C. to 250° C. As such, suitable substrate materials are limited to those substrate materials (e.g., glass, Si) that can withstand the high processing temperatures without detrimental effects (e.g., dimensional distortion such as warping, etc.). Another drawback is that conductive patterning of conductive material around or in 3D structures by semiconductor processing techniques is very difficult and often avoided due to the complexity introduced by 3D surface structures.

For macro level electrical conductive wiring or pattern deposition, conductors are printed by an Inkjet process wherein droplets of conductive ink are deposited onto the substrate surface of interest, such as the surface of a glass substrate, an indium-tin-oxide (ITO) surface (e.g., ITO on glass), silicon (Si), silicon oxides (e.g., SiOx on Si), silicon nitrides (SiNx on Si), etc., to form the desired conductive patterns. Most known aqueous or non-aqueous media inks wet rapidly or are very easily absorbed by most surfaces. Such wetting/absorption causes the deposited ink to spread wider than the initial deposited droplet which makes it difficult if not impossible to achieve narrow line widths less. Thus, although this technique can be used to deposit conductive lines on large area substrates, one drawback of this technique is that the minimum line width is usually greater than about 100 micrometers (microns, μm). Attempts to use this technique to fabricate conductive lines having widths less than about 100 μm commonly results in non-uniform conductive line-widths (e.g., conductive trace with ragged edges) and varying conductor thicknesses (i.e., non-uniform conductive trace heights) which undesirably causes resistance to vary within an electrical trace and hence poor performance. Another drawback of conventional inkjet processing using commercial liquid media is that conductive line/pattern deposition requires exposing the substrate to high temperatures (>120° C.) to cure the ink so as to drive off solvent(s) in the ink, and to sinter the nanoparticles to leave behind the desired conductive line/pattern. In such cases, the sheet resistance of the metal lines is related to and controlled by the sintering temperature, and high temperatures (>150° C.) are required for achieving lower resistance (a few ohms/sq). As such, suitable substrate materials are limited to those substrate materials (e.g., glass, Si) that can withstand the high processing temperatures without detrimental effects (e.g., dimensional distortion such as warping, etc.).

Selective coating of conductors on 3D surfaces is only achievable by ink jet printing of specific designs. As such, the minimum conductive pattern or line width of about 100 μm limits the applications. Wide interconnect lines having widths greater than about 100 μm also limits the spacing or pitch between lines to about 75 μm or more. Thus, packing density of the lines is low. Likewise, selective printing of conductive material in the recessed areas (valleys) between regular or randomized 3D structures having a pitch of less than about 75 μm, or printing of conductive material on the top of the 3D structures, generally is not possible.

Due to high processing temperatures typically in excess of about 120° C., semiconductor and conventional inkjet processing techniques are not suitable techniques to deposit conductive line/patterns onto flexible polymeric membranes (e.g., polymeric membranes utilized in various types of optical displays) or onto flexible polymeric substrates utilized in flexible electronics applications. Substrate exposure to such high processing temperatures limits the substrate materials to those materials (e.g., glass, Si) that can withstand the high processing temperatures without detrimental effects such as dimensional distortion due to warping, melting, micro-cracking, etc. Polymeric materials used to fabricate flexible plastic substrates are not suitable substrate materials for conductive line/pattern deposition using either semiconductor or inkjet processing techniques because high temperature processing of flexible polymer material typically causes undesirable micro-cracking and/or diffusion of conductive material into the flexible polymer material.

### BRIEF DESCRIPTION OF THE DRAWINGS

For a detailed description of exemplary embodiments of the invention, reference will now be made to the accompanying drawings in which:

FIG. 1 shows a method in accordance with first embodiment of the invention;

FIG. 2 shows a substrate;

FIG. 3 shows a substrate with various 3-D structures deposited or embossed thereon;

FIG. 4 illustrates conductive material deposited in the valleys between the 3-D structures of FIG. 3 in accordance with various embodiments of the invention;

FIG. 5 shows a perspective view of conductive material in the valleys between 3-D structures;

FIG. 6 shows a method in accordance with a second embodiment of the invention;

FIGS. 7-8 show several examples of conductive patterns formed by the method of FIG. 6; and

FIGS. 11 and 12 show an application of the methods described herein in which conductive patterns are formed in a panel for driving a display.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

In the embodiments disclosed herein, the surface energy of a substrate is modified before depositing a conductive liquid (e.g., an ink) thereon. The term “surface energy” refers to a property of a material that draws surface molecules inward. In some embodiment, the surface energy of the substrate surface in regions on which the conductive liquid is to be deposited is modified so as to approximately match the surface energy (surface tension) of the conductive liquid itself. By approximately matching the surface's surface energy to that of the conductive liquid, the conductive liquid adheres to the desired regions and does not adhere to the remaining regions which may have a much lower surface energy. In other embodiments, the surface energy of the regions on which the conductive liquid is not to adhere is modified to reduce its surface energy in an “inverted pattern” of where the conductive liquid is to adhere. Then, when the conductive liquid coats the substrate surface, the liquid adheres only to the regions whose surface energy was not reduced. These embodiments are described in greater detail below.

The embodiments described herein permit thin conductive lines and 3-D geometries (e.g., as thin as 1 μm or smaller) to be formed on a substrate and formed so at much lower temperatures than those noted above. For example, the processes described herein can be performed at temperatures lower than 45° C. (the temperature of the plating bath discussed below). Further, the substrate material used may include silicon, glass, acrylate, kapton, polycarbonate, Mylar, polyethylene terephthalate (PET), and the like. The substrate may be flexible if desired.

As used herein, the term “pattern” is generally used to refer to the desired pattern of the conductive material formed by the conductive liquid. The pattern may include straight lines (e.g., a set of spaced, parallel lines) or any arbitrary pattern or 3-D formation of conductive material.

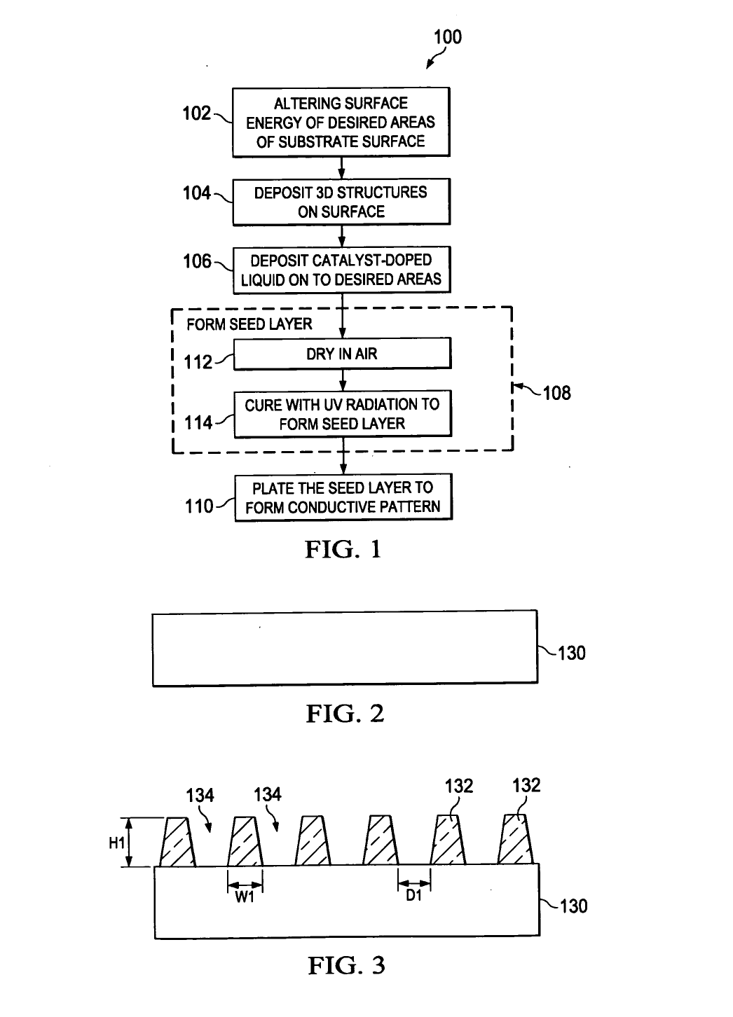

FIG. 1 illustrates an embodiment of the method 100 in which the surface energy of the areas of the substrate is modified to approximate the surface energy of the conductive liquid. The substrate areas so modified are the areas where the conductive material formed from the conductive liquid is to remain thereby forming conductive pathways across the substrate. To the extent possible, some of the actions depicted in FIG. 1 may be performed in a different order from that shown and some actions may be performed in parallel, not sequentially.

At 102, the method comprises altering the surface energy of the desired areas of the substrate surface (i.e., the areas in which conductive material is desired to be formed). This action can be performed by depositing, on the substrate surface, a substance having a surface energy in the range of 20 to 50 dynes/cm. In some embodiments, the deposited material has a surface energy in the range of 25 to 35 dynes/cm. A suitable material to deposit on the substrate surface includes acrylate. Altering the surface energy of the desired areas may entail increasing the surface energy of those areas of the substrate surface by at least 20%. FIG. 2 depicts a side view of a substrate 130.

At 104, the method comprises depositing three-dimensional (3-D) structures on the surface of the substrate. Such structures may be of any shape or size. In some embodiments, such structures are transparent and function to cause light to be extracted from a light guide to which the substrate is coupled. The use of a light guide is described below with regard to FIGS. 9 and 10. FIG. 3 shows a side view of the substrate 130 of FIG. 2 on which 3-D structures 132 are deposited. The 3-D structures 132 form valleys 134 therebetween. The surface energy of the 3-D structures may approximate the surface energy of the altered regions of the substrate and may be formed of acrylate as well. In some embodiments, the surface energy of the 3-D structures 132 is within 10% of the surface energy of the substrate surface.

The 3-D structures 132 comprise raised or protruding structures that delimit the width and shape of the desired conductive pattern. In some embodiments, the structures 132 may have a height (H1) of 6 μm, a width of 6 μm, and a distance (D1) between ridges of 12 μm. The structures may also have a height of a few nanometers to several microns (100 nm to 100 μm). The distance D1 defines the pitch of the conductive pattern.

The structures 132 may be formed via any of a variety of techniques. In at least one embodiment, the patterning and fabrication of the structures 132 is performed using ultraviolet (UV)-embossing of photoacrylates or hot embossing on polyurethane, polycarbonate, etc. In the case, discussed below with regard to FIGS. 9 and 10, in which the structures 132 and base layer are part of an optical display, a microlens array or optical gratings are etched on a photomask, which are then replicated on photoresist master using photolithography, laser ablation or laser polymerization. A replicated stamp (PDMS, silicone) is created by dispensing a thermal-setting resin onto the mater and thermally curing it at 90° C. in an oven. A UV-curable acrylate resin is spread evenly over the surface of the base layer (thickness may be in the range of 2 to 200 μm). The stamp then is brought in contact with the base layer under a load for a certain length of time, allowing the pattern to transfer onto the substrate surface. The combination of stamp and base layer is then UV-cured in an enclosed UV-chamber and exposed to a pre-determined UV dose level to cure the acrylate. The stamp is then peeled off, leaving the desired microstructure pattern that is replicated on the acrylate base layer.

At 106, the method comprises depositing a catalyst-doped conductive liquid (e.g., an ink) on to the desired areas. The conductive liquid chosen in this step should have a surface energy (surface tension) approximately equal to the surface energy of the altered regions of the substrate 130. In some embodiments, the conductive liquid has a surface energy in the range of 20 to 50 dynes/cm. In some embodiments, the liquid's surface energy may be in the narrower range of 25 to 35 dynes/cm, or further still in the range of 29 to 33 dynes/cm. The conductive liquid preferably is a metal catalyst-doped liquid (e.g., palladium (Pd) catalyst-doped liquid) such as an ink. For example, the liquid may be a Pd acetate mixed in ethyl lactate. In some embodiments, the depositing (printing) of the conductive liquid is performed using a Xennia Inkjet printer (based on Xaar Printhead Technology). The print gap, ink volume, print speed, etc. are adjustable based on the application at hand and thus may be varied as desired.

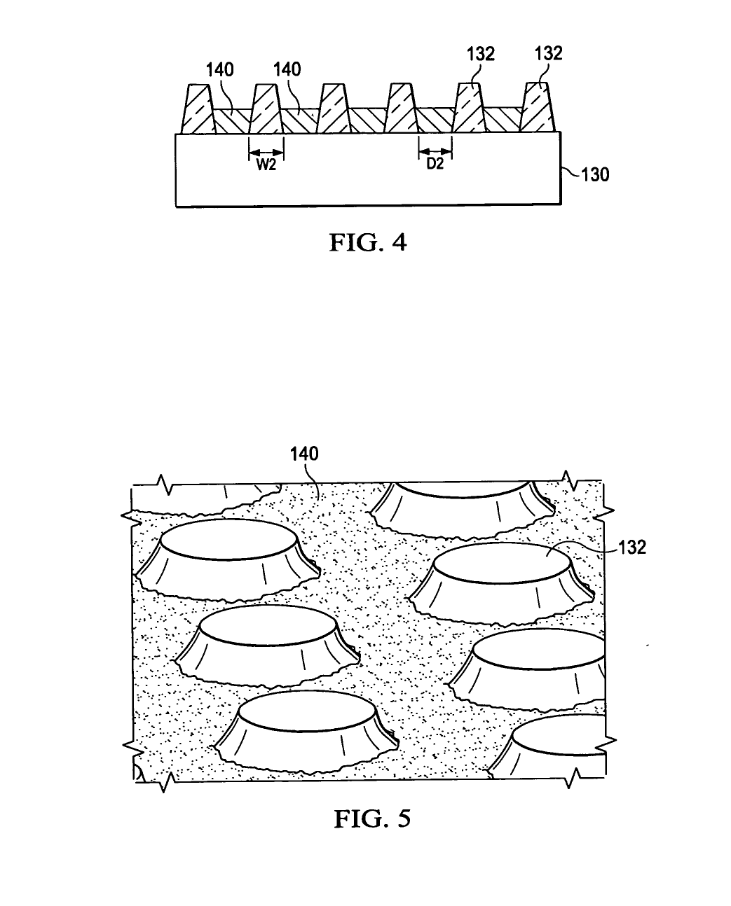

FIG. 4 shows that the conductive liquid 140 readily settles into the valleys 134. The close match between the surface energy of the substrate and that of the conductive liquid causes the liquid 140 to settle in the valleys in a generally constant depth fashion. Because the surface energy of the substrate 130 and 3-D structures 132 is not excessively low, the conductive liquid does not form beads. Because the surface energy of the substrate is not too high, the liquid does not spread too quickly. If the surface energy of the substrate was too high, the liquid would likely cover and adhere to the tops of the 3-D structures 132 themselves which would be undesirable for display applications in which the structures must be transparent.

At 108 in FIG. 1, the method further comprises forming a seed layer using the deposited conductive liquid. This action can be performed by allowing the deposited conductive liquid to dry (e.g., for a few hours) on the substrate (112) and curing the remaining material with, for example, UV radiation (114). The UV radiation used may have a wavelength of, for example, 365 nm.

At 110, the method comprises plating the seed layer to form the desired conductive pattern. This action can be performed by depositing a desired metal, such as copper, onto the surface of the seed layer by way of a plating process such as electroless plating or electrochemical plating. The temperature of the plating bath may at or less than 45° C. Using such plating processes, the metal (e.g., copper) will selectively plate onto the metallic seed layer thereby forming the desired electrically conductive pattern. For example, the substrate 130 may be submerged in a copper bath. Upon removing the substrate, only those portions of the surface having the metallic seed layer are coated with copper. With regard to FIGS. 3 and 4, the width D2 of the conductive copper in the valleys 132 will be equal to D1 (e.g., 12 μm) and the spacing W2 between the conductive portions will be equal to W1 (e.g., 6 μm). In general, line widths down to 4 μm or narrower with a 4 μm (or smaller) pitch are possible with this technique.

FIG. 5 shows a perspective view of the substrate with 3-D structures 132 and conductive material 140 formed therebetween as described above.

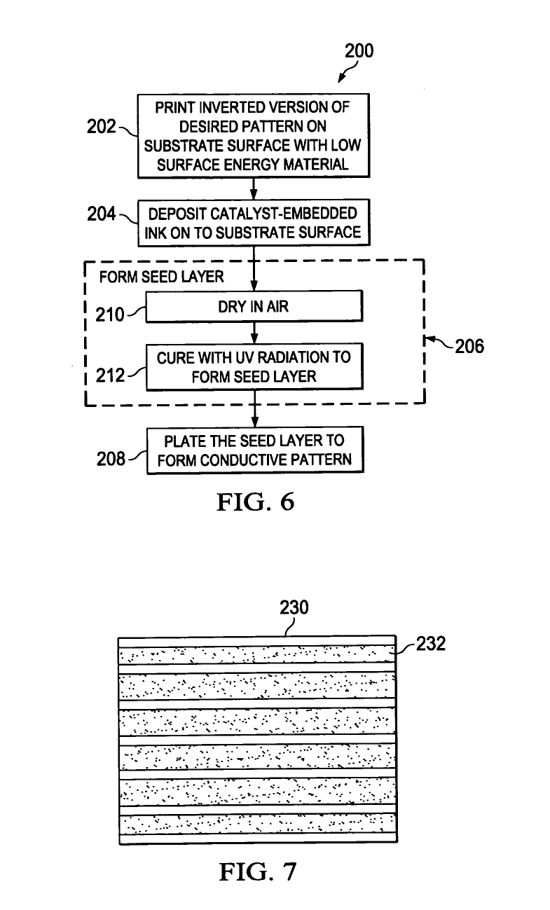

FIG. 6 provides a method 200 in accordance with another embodiment of the invention. The embodiment of FIG. 6 does not include 3-D structures to delimit the width and shape of the desired conductive pattern. Instead, the embodiment of FIG. 6 includes altering the surface energy of the surface of the substrate where conductive liquid is not desired. The alteration may comprise decreasing the surface energy where conductive liquid is not desired to a low enough level where conductive liquid will not readily adhere. In the embodiment of FIG. 6, the substrate may be formed of a material (at least its outer surface layer on which the conductive pattern is to be formed) that has a surface energy that approximates or is greater than the surface energy of the conductive liquid to be deposited thereon. Alternatively, the substrate initially may be coated with a material that approximates or is greater than the surface energy of the conductive liquid to be deposited.

At 202, the method of FIG. 6 comprises printing an inverted version of the desired pattern on the substrate surface with a low surface energy material. That is, the regions of the substrate on which conductive material is not desired are coated with a low surface energy material. Such regions are referred to as an “inverted pattern.” The low surface energy material may comprise, for example, a Self-Aligning Monolayer (SAM) layer formed by vapor deposition of fluorinated molecules or deposited as a liquid and then driven off the volatile solvent base. In some embodiments, the surface energy of such material is 50% or more lower than the surface energy of the remaining area on which conductive material is desired. For example, the surface energy of the material printed in 202 is less than 20 dynes/cm. The surface energy of the remaining portions of the substrate is significantly higher than the surface energy of the inverted pattern (which is 520 dynes/cm). In some embodiments, the substrate comprises polycarbonate or PET (approximately 40 dynes/cm) or glass (≧70 dynes/cm).

At 204, the method comprises depositing a catalyst-doped conductive liquid (e.g., an ink) on to the desired areas. The conductive liquid chosen in this step should have a surface energy (surface tension) substantially greater than the surface energy of the regions of the substrate that are part of the inverted pattern. In some embodiments, the conductive liquid has a surface energy in the range of 20 to 50 dynes/cm. In some embodiments, the liquid's surface energy may be in the range of 25 to 35 dynes/cm, or more particularly in the range of 29 to 33 dynes/cm. The conductive liquid preferably is a metal catalyst-doped liquid (e.g., palladium catalyst-doped liquid) such as an ink.

The conductive fluid settles into the higher surface energy areas only and not in the inverted pattern which has a lower surface energy. The substrate can be coated with such a conductive liquid, but the liquid will not adhere to the region of the inverted pattern due to its low surface energy. Instead, the conductive liquid will adhere to the remaining regions which comprise the regions in which conductive material is desired.

At 206, the method comprises forming a seed layer using the deposited conductive liquid. This action can be performed by allowing the deposited conductive liquid to dry on the substrate (201) and curing the remaining material with, for example, ultraviolet (UV) radiation (212).

At 208, the method comprises plating the seed layer to form the desired conductive pattern. This action can be performed by depositing a desired metal, such as copper, onto the surface of the seed layer by way of a plating process such as electroless plating or electrochemical plating. Using such plating processes, the metal (e.g., copper) will selectively plate onto the metallic seed layer thereby forming the desired electrically conductive pattern. For example, the substrate may be submerged in a copper bath. Upon removing the substrate, only those portions of the surface having the metallic seed layer are coated with copper. The method described herein is not limited to copper but other platable metals such as nickel may also be coated using the compatible catalyst-incorporated liquid ink.

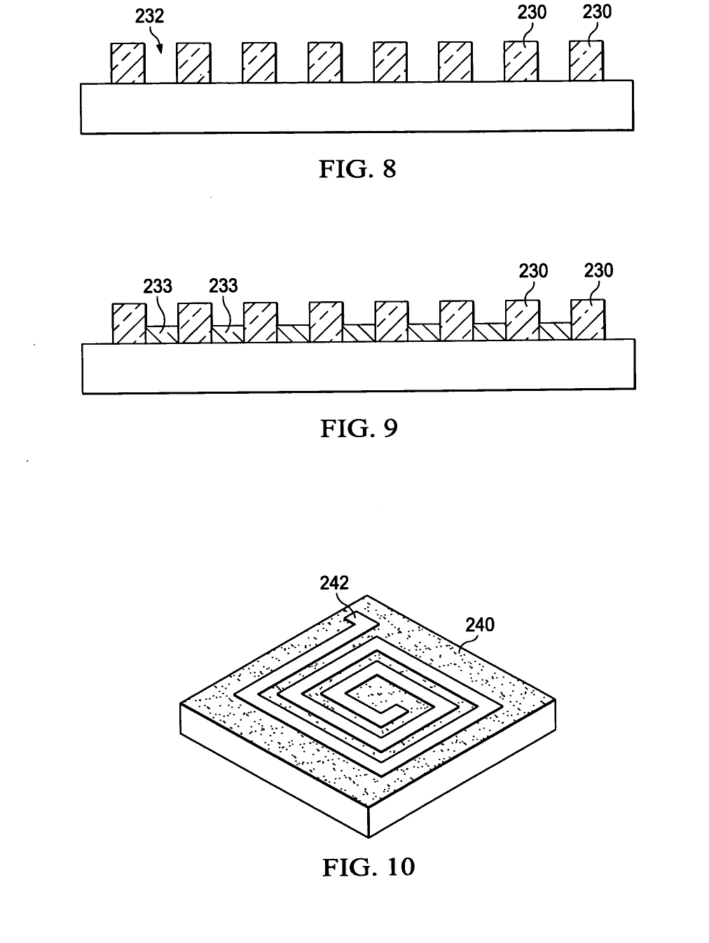

FIGS. 7-10 show two illustrative embodiments of patterns that can be performed on a flat substrate. In FIG. 7, the conductive lines 230 are generally straight and parallel to each other. Regions 232 are the regions in which the low surface energy (e.g., less than 20 dynes/cm) material is printed. FIGS. 8 and 9 show side views of the embodiment of FIG. 7. In FIG. 9, low surface energy material 233 is shown in regions 232. In FIG. 10, the low surface energy material is printed at 240 in an inverted pattern to pattern 242 which contains the conductive material.

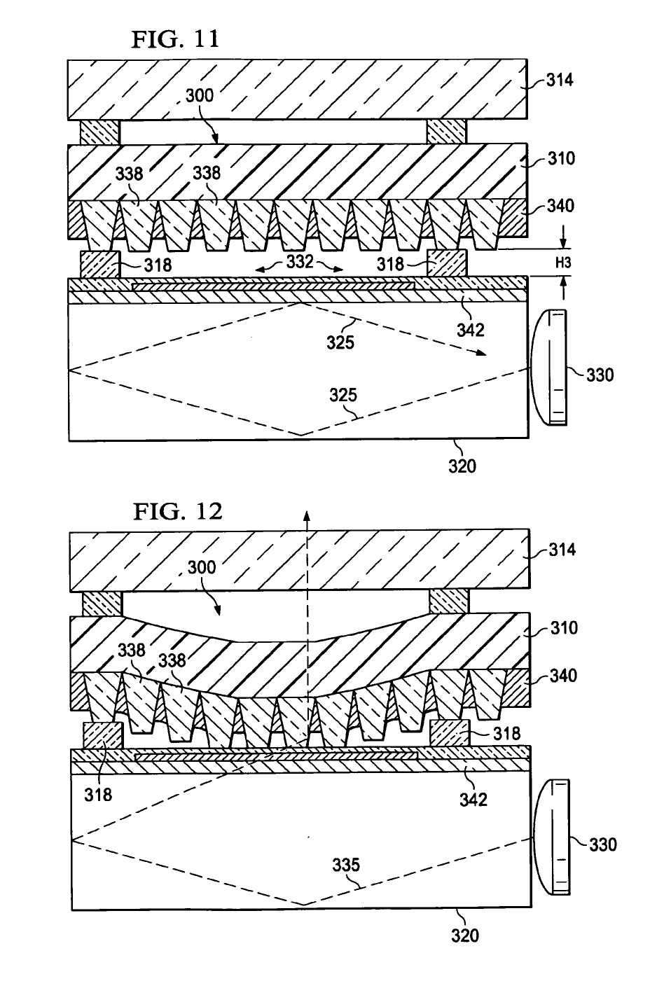

FIGS. 11 and 12 depict an application in which a microlens film 310 is placed adjacent a light guide 320 as part of a display. A portion of the microlens film 310 is shown corresponding to a single pixel 300 in a display. A light source 330 (e.g., a light emitting diode (LED)) is positioned to the side of the light guide 320 and thus injects light into the light guide from the side. The light guide 320 may be constructed from a variety of transparent materials such as glass, polycarbonate, or acrylate. The light 325 injected into the light guide 320 by the LED 330 reflects off the top and bottom surfaces of the light guide by way of total internal reflection (TIR), which is a function of the angle of the light beam and the coefficient of refraction of the light guide relative to the coefficient of refraction of air 332.

The microlens film 310 is positioned adjacent the light guide 320 by way of standoffs 318 which separate the 3-D structures 338 formed on the microlens film from the light guide. FIG. 11 shows the pixel 300 in an “off” position. Because the structures 332 are separated (H3) by more than a threshold distance from the light guide 320, the light from the light guide cannot escape the guide. To turn the pixel 300 “on,” thereby causing light from the light guide 320 to escape the light guide, a portion of the microlens film 310 adjacent pixel 300 must be brought close to, or in contact with, the light guide 320. The structures 338 are transparent and have a coefficient of refraction such that the total internal reflection of the light will be frustrated and light will escape from the light guide into the structures 338 as shown in FIG. 12 (pixel on).

A sufficient electrical potential difference placed across the pixel causes the pixel to bend and snap across the gap H3 due to electrostatic attraction. The conductive material 340 embedded in the valleys between the structures 338 is formed by one or more of the techniques described above. The structures 338 must remain transparent and the techniques described herein help ensue the conductive material does not remain coated on the structures 338. Instead, the conductive liquid falls into the valleys between the structures as a result of surface energy modification of the substrate. Reference numeral 342 refers to the conductor on the opposite side of the gap to which the voltage is applied.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method for forming a conductive pattern on a substrate surface, comprising:
altering the surface energy of the substrate surface;
depositing a catalyst-doped liquid on to said substrate surface;
forming a seed layer from said deposited catalyst-doped liquid; and
plating the seed layer thereby forming the conductive pattern.

2. The method of claim 1 further comprising depositing 3-D structures on said substrate surface before depositing said catalyst-doped liquid on to said surface.

3. The method of claim 2 wherein the 3-D structures define valleys between adjacent 3-D structures and wherein the conductive pattern comprises conductive material in valleys between said 3-D structures.

4. The method of claim 3 wherein the surface energy of the 3-D structures is within 10% of the surface energy of the surface energy of the substrate surface.

5. The method of claim 2 wherein altering the surface energy comprises altering the surface energy to a level at which said deposited catalyst-doped liquid will adhere.

6. The method of claim 1 wherein altering the surface energy comprises increasing the surface energy of the substrate surface.

7. The method of claim 1 wherein altering the surface energy comprises depositing a substance having a surface energy in the range of 20 to 50 dynes/cm.

8. The method of claim 1 wherein altering the surface energy comprises depositing a substance having a surface energy in the range of 25 to 35 dynes/cm.

9. The method of claim 1 wherein altering the surface energy comprises depositing an acrylate on said substrate surface.

10. The method of claim 1 wherein depositing the catalyst-doped liquid on to said substrate surface comprises depositing a liquid having a surface energy in the range of 20 to 50 dynes/cm.

11. The method of claim 1 wherein depositing the catalyst-doped liquid on to said substrate surface comprises depositing a liquid having a surface energy in the range of 25 to 35 dynes/cm.

12. The method of claim 1 wherein depositing the catalyst-doped liquid on to said substrate surface comprises depositing a liquid having a surface energy in the range of 29 to 33 dynes/cm.

13. The method of claim 1 wherein depositing the catalyst-doped liquid on to said substrate surface comprises depositing a metal catalyst-doped liquid on to said substrate surface.

14. The method of claim 1 wherein depositing the catalyst-doped liquid on to said substrate surface comprises depositing a palladium catalyst-doped liquid on to said substrate surface.

15. The method of claim 1 wherein forming the seed layer comprises drying and curing said deposited catalyst-embedded liquid.

16. A substrate with a conductive pattern formed by the method of claim 1.

17. A method for forming a conductive pattern on a substrate surface, comprising:
altering the surface energy of a first portion of the substrate surface to be at a lower surface energy than the surface energy of a second portion of the substrate surface;
depositing a catalyst-doped liquid on to said substrate surface, wherein the catalyst-doped liquid adheres to the second portion and not the first portion of the substrate surface;
forming a seed layer from said deposited catalyst-doped liquid; and
plating the seed layer thereby forming the conductive pattern.

18. The method of claim 17 wherein altering the surface energy of said first portion comprises depositing a substance on said first portion, said substance having a surface energy less than 20 dynes/cm.

19. The method of claim 17 wherein altering the surface energy of said first portion comprises forming a SAM layer by chemical vapor deposition of fluorinated molecules.

20. The method of claim 17 wherein depositing the catalyst-doped liquid on to said substrate surface comprises depositing a liquid having a surface energy in the range of 20 to 50 dynes/cm.

21. The method of claim 17 wherein depositing the catalyst-doped liquid on to said substrate surface comprises depositing a liquid having a surface energy in the range of 25 to 35 dynes/cm.

22. The method of claim 17 wherein depositing the catalyst-doped liquid on to said substrate surface comprises depositing a liquid having a surface energy in the range of 29 to 33 dynes/cm.

23. The method of claim 17 wherein depositing the catalyst-doped liquid on to said substrate surface comprises depositing a metal catalyst-doped liquid on to said substrate surface.

24. The method of claim 17 wherein depositing the catalyst-doped liquid on to said substrate surface comprises depositing a palladium catalyst-doped liquid on to said substrate surface.

25. The method of claim 17 wherein forming the seed layer comprises drying and curing said deposited catalyst-embedded liquid.

26. A substrate with a conductive pattern formed by the method of claim 17.
